(19) United States
(12) Patent Application Publication
(10) Pub. No.: US 2026/0065948 A1
(43) Pub. Date: Mar. 5, 2026

(54) MEMORY DEVICE AND METHOD OF MANUFACTURING THE SAME

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/819,617

(22) Filed: Aug. 29, 2024

(51) Int. Cl. G11C 5/06; G11C 11/417; H01L 23/528; H10B 10/00

(52) U.S. Cl. CPC G11C 5/063; G11C 11/417; H10B 10/12

(57) ABSTRACT

A memory device is provided. The memory device comprises multiple cell groups arranged along a first direction and a second direction perpendicular to the first direction. Each cell group comprises a first bit cell and a second bit cell arranged next to the first bit cell along the first direction. The first bit cell is coupled to a first word line extending along the first direction, and the second bit cell is coupled to a second word line extending along the first direction. The first bit cell and the second bit cell share a bit line extending along the second direction.

### BACKGROUND

The integrated circuit can typically include individual devices formed in a device layer, such as transistors, capacitors, and the like. One or more layers of metal are then formed on the individual devices to provide connections between individual devices and to external devices. Front-end-of-line (FEOL) is the first part of making an integrated circuit in which individual devices are formed on a wafer. The front-end process usually covers all steps before (but not including) the deposition of the metal layers. The back-end-of-line (BEOL) is the second part of the integrated circuit in which individual devices are connected by wires or metal layers. The back-end process typically begins by depositing a first metal layer on the device layer. To optimize layout of the integrated circuit, individual devices may be connected by metal layers in a backside of the wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of a memory device, in accordance with some embodiments of the present disclosure.

FIG. 2A is a circuit diagram of an example of the bit cell corresponding to the memory device in FIG. 1, in accordance with some embodiments of the present disclosure.

FIG. 2B is a circuit diagram of an example of the bit cell in FIGS. 1 and 2A, in accordance with some embodiments of the present disclosure.

FIG. 3A is a schematic diagram of an example of a cell group of the bit cells in FIGS. 1 and 2A-2B in a top view, in accordance with some embodiments of the present disclosure.

FIG. 3B is a schematic diagram of a memory device configured with respect to the memory device including cell groups corresponding to FIGS. 1, 2A-2B and 3A in a top view, in accordance with some embodiments of the present disclosure.

FIG. 3C is a schematic diagram of a memory device configured with respect to the memory devices corresponding to FIGS. 1, 2A-2B and 3A in a top view, in accordance with some embodiments of the present disclosure.

FIG. 4 is a schematic diagram of an example of layers of the memory device of FIGS. 1, 2A-2B and 3A-3C in accordance with some embodiments of the present disclosure.

FIGS. 5A-5B are layout diagrams of front side of a cell group configured with respect to the cell groups corresponding to the memory devices of FIGS. 1, 2A-2B, 3A-3C and 4, in accordance with some embodiments of the present disclosure.

FIGS. 5C-5D are layout diagrams of backside of the cell group of FIGS. 5A-5B, in accordance with some embodiments of the present disclosure.

FIG. 6 is layout diagram of front side of a cell group configured with respect to the cell group of FIGS. 5A-5D and the cell groups corresponding to the memory devices of FIGS. 1, 2A-2B, 3A-3C and 4, in accordance with some embodiments of the present disclosure.

FIG. 7 is layout diagram of front side of a cell group configured with respect to the cell group of FIGS. 5A-5D and the cell groups corresponding to the memory devices of FIGS. 1, 2A-2B, 3A-3C and 4, in accordance with some embodiments of the present disclosure.

FIG. 8 is layout diagram of front side of a cell group configured with respect to the cell group of FIG. 7, the cell group of FIGS. 5A-5D and the cell groups corresponding to the memory devices of FIGS. 1, 2A-2B, 3A-3C and 4, in accordance with some embodiments of the present disclosure.

FIG. 9 is layout diagram of backside of a cell group configured with respect to the cell groups of FIGS. 5A-5D, 6-8 and the cell groups corresponding to the memory devices of FIGS. 1, 2A-2B, 3A-3C and 4, in accordance with some embodiments of the present disclosure.

FIG. 10 is layout diagram of backside of a cell group configured with respect to the cell groups of FIGS. 5A-5D, 6-9 and the cell groups corresponding to the memory devices of FIGS. 1, 2A-2B, 3A-3C and 4, in accordance with some embodiments of the present disclosure.

FIG. 11 is a flowchart diagram of a method for manufacturing the memory devices, bit cells, cell groups as shown in FIGS. 1, 2A-2B, 3A-3C, 4, 5A-5D, 6-10, in accordance with some embodiments of the present disclosure.

FIG. 12 is a block diagram of an electronic design automation (EDA) system for designing the integrated circuit layout design, in accordance with some embodiments of the present disclosure.

FIG. 13 is a block diagram of IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. The term mask, photolithographic mask, photomask and reticle are used to refer to the same item.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

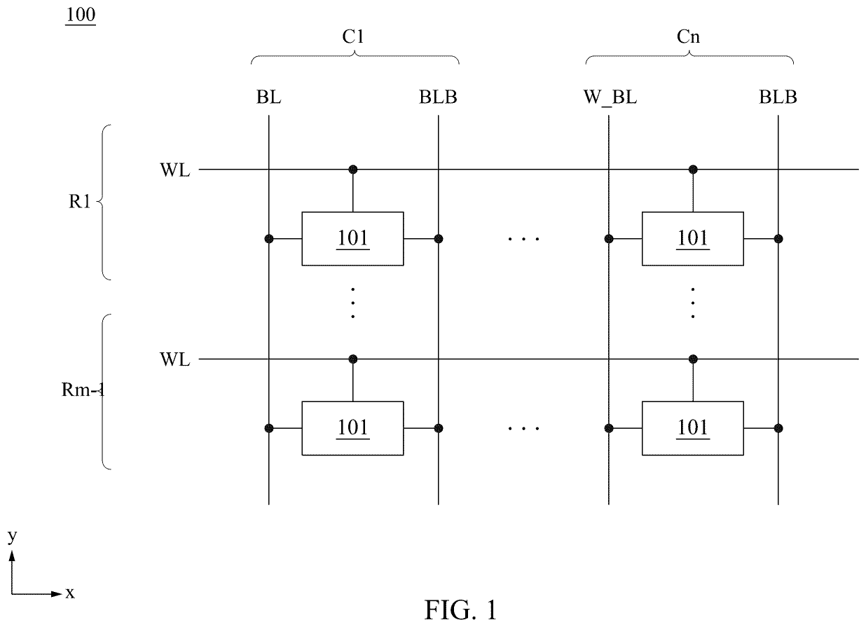

Reference is now made to FIG. 1. FIG. 1 is a circuit diagram of a memory device 100, in accordance with some embodiments of the present disclosure. For illustration, the memory device 100 includes a memory array of bit cells 101. The bit cells 101 are arranged in rows R1-Rm and columns C1-Cn. In some embodiments, the bit cells 101 are static random access memory (SRAM) cells. It should be noted that the rows R1-Rm and the column C1-Cn are not physical rows and columns of the bit cells 101. The rows R1-Rm and the column C1-Cn correspond to rows and columns for memory addressing of the bit cells 101.

As shown in FIG. 1, the memory device 100 further includes word lines WL, bit lines BL and BLB. The bit cells 101 in a same row are coupled to a corresponding word line WL. The bit cells 101 in a same column are coupled to a corresponding bit line BL and a corresponding bit line BLB.

In practice, a word line WL is configured to transmit a word line signal to activate the row of bit cells 101 coupled to the word line WL in a write/read operation.

In a write operation, the lines BL and BLB are configured to transmit write data to the column of bit cells 101 coupled to the lines BL and BLB. In some embodiments, the bit line BL and the bit line BLB coupled to the same column are configured as a pair of complementary bit lines (i.e., the bit line BLB is a complementary bit line of the bit line BL). In some embodiments, in the write operation, the logic level on the bit line BL is inverted to the logic level on the bit line BLB to write a bit of data.

In a read operation, the pair of bit lines BL and BLB are further configured to receive read data from the activated bit cell 101 in the column of bit cells 101 coupled to the pair of bit lines BL and BLB.

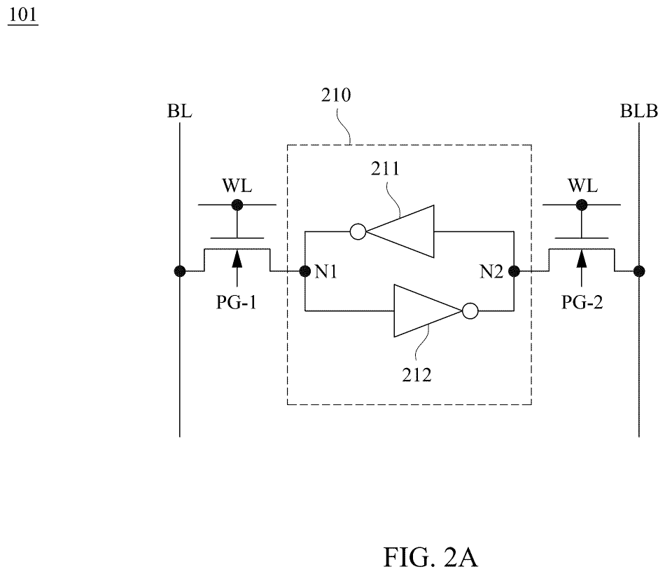

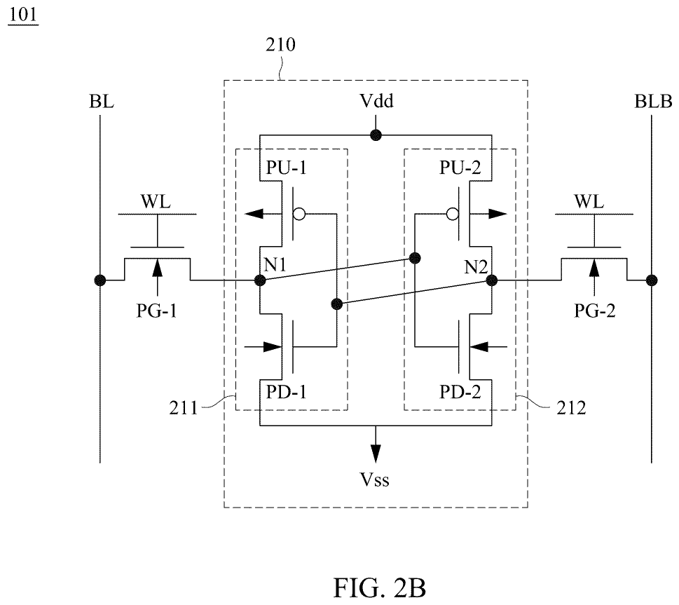

Reference is now made to FIG. 2A. FIG. 2A is a circuit diagram of an example of the bit cell 101 corresponding to the memory device 100 in FIG. 1, in accordance with some embodiments of the present disclosure. With respect to the embodiments of FIG. 1, like elements in FIG. 2A are designated with the same annotations and/or reference numbers for ease of understanding. The specific operations of similar elements, which are already discussed in detail in above paragraphs, are omitted herein for the sake of brevity.

For illustration, the bit cell 101 includes a latch 210, a transistor PG-1 and a transistor PG-2. The latch 201 includes an inverter 211 and an inverter 212.

As shown in FIG. 2A, gate terminals of the transistors PG-1 and PG-2 is coupled to the word line WL corresponding to the row of the bit cell 101. A source/drain terminal of the transistor PG-1 is coupled to the bit line BL corresponding to the column of the bit cell 101. A drain/source terminal of the transistor PG-1 is coupled to a node N1.

Similarly, a source/drain terminal of the transistor PG-2 is coupled to the bit line BLB corresponding to the column of the bit cell 101. A drain/source terminal is coupled to a node N2.

The inverters 211 and 212 are cross coupled to each other. An output terminal of the inverter 211 and an input terminal of the inverter 212 are coupled together to the node N1. An output terminal of the inverter 212 and an input terminal of the inverter 211 are coupled together to the node N2.

In some embodiments, the nodes N1 and N2 are storage nodes for storing a bit of data. The node N2 is a complementary data node to the node N1. Specifically, in some embodiments, when the node N1 has a high logic level and the node N2 has a low logic level, the bit cell 101 stores a first logic value (logic one or logic zero). When the node N1 has a low logic level and the node N2 has a high logic level, the bit cell 101 stores a second logic value (logic one or logic zero) inverted to the first logic value.

According to some embodiments of the present disclosure, in a write operation, a word line signal is transmitted through the word line WL to activate the bit cell 101. For example, in the write operation, a voltage level of the word line WL is pulled high to turn on the transistors PG-1 and PG-2 and the bit cell 101 is activated. When the transistors PG-1 and PG-2 are turned on (bit cell 101 activated), a bit of data transmitted by the bit lines BL and BLB are programed into the bit cell 101 by adjusting the voltage levels of the nodes N1 and N2. Then, the transistors PG-1 and PG-2 are turned off. The bit cell 101 stores the bit of data by maintaining the voltage levels of the node N1 and N2.

In a read operation, a word line signal is transmitted through the word line WL to activate the bit cell 101. For example, in the read operation, a voltage level of the word line WL is pulled high to turn on the transistors PG-1 and PG-2 and the bit cell 101 is activated. When the transistors PG-1 and PG-2 are turned on (bit cell 101 activated), voltage levels on the bit lines BL and BLB are adjusted according to the data stored in the bit cell 101 (the voltage level of the nodes N1 and N2).

Reference is now made to FIG. 2B. FIG. 2B is a circuit diagram of an example of the bit cell 101 in FIGS. 1 and 2A, in accordance with some embodiments of the present disclosure. With respect to the embodiments of FIGS. 1 and 2A, like elements in FIG. 2B are designated with the same annotations and/or reference numbers for ease of understanding.

As shown in FIG. 2B, in some embodiments, the inverter 211 includes a transistor PU-1 and a transistor PD-1. The inverter 212 includes a transistor PU-2 and a transistor PD-2.

A source/drain terminal of the transistor PU-1 is coupled to a supply voltage VDD. A source/drain terminal of the transistor PD-1 is coupled to a supply voltage VSS. In some embodiments, the supply voltage VDD is higher than the supply voltage VSS. In some embodiments, the supply voltage VSS is a ground reference voltage.

Drain/source terminals of the transistors PU-1 and PD-1 are coupled together as the output terminal of the inverter 211 and are coupled to the node N1.

Gate terminals of the transistors PU-1 and PD-1 are coupled together as the input terminal of the inverter 211 and are coupled to the node N2.

Similarly, A source/drain terminal of the transistor PU-2 is coupled to a supply voltage VDD. A source/drain terminal of the transistor PD-2 is coupled to a supply voltage VSS.

Drain/source terminals of the transistors PU-2 and PD-2 are coupled together as the output terminal of the inverter 212 and are coupled to the node N2.

Gate terminals of the transistors PU-2 and PD-2 are coupled together as the input terminal of the inverter 212 and are coupled to the node N1.

In some embodiments, the transistors PG-1, PG-2, PD-1 and PD-2 are of a first conductive type. The transistors PU-1 and PU-2 are of a second conductive type different from the first conductive type. In some embodiments, the transistors PG-1, PG-2, PD-1 and PD-2 are n type metal-oxide-semiconductor field-effect transistors (NMOS). The transistors PU-1 and PU-2 are p type metal-oxide-semiconductor field-effect transistors (PMOS).

In some embodiments, the transistors PG-1, PG-2, PU-1, PU-2, PD-1 and PD-2 are fin field-effect transistors (FinFET), gate-all-around (GAA) transistors, complementary field-effect transistors (CFET), silicon on insulator (SOI) planar transistors, SOI fin-structure (3D) transistors, SOI GAA transistors or the combination thereof. The channel region of GAA transistors can be nano-wire, nano-sheet, fork-sheet, vertically stacked multiple channels, of the combination thereof.

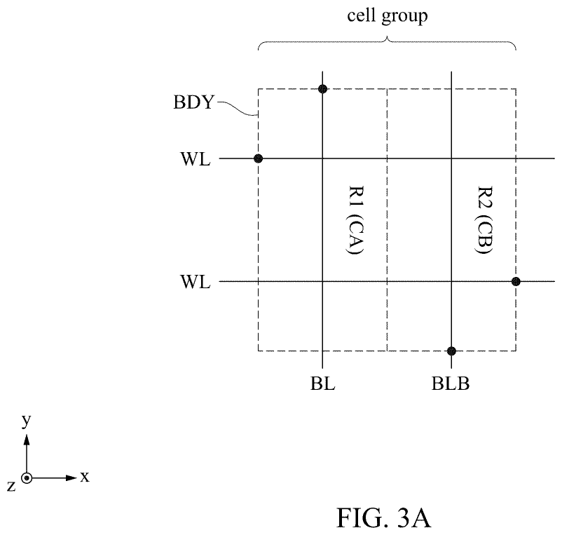

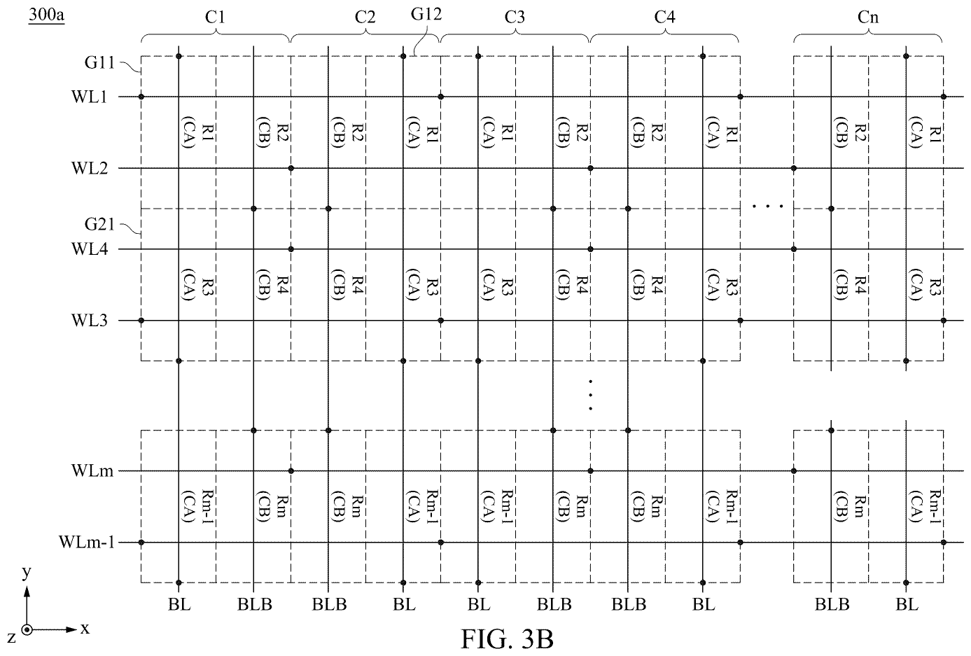

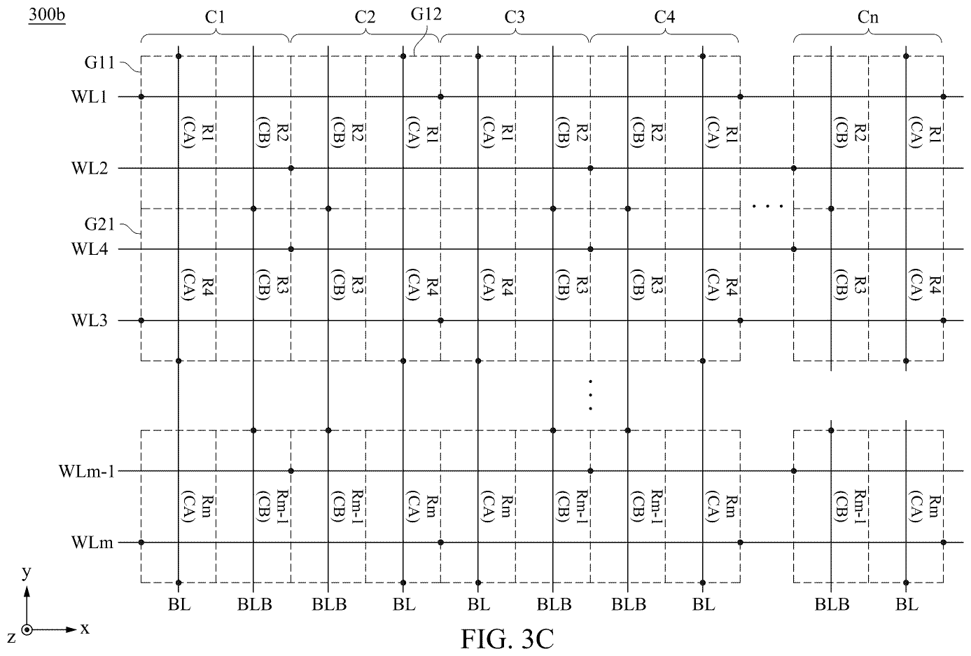

In some embodiments, the bit cells 101 in the memory device 100 are arranged into cell groups. Each cell group includes bit cells 101 of different rows. Further details about arrangement of the cell groups are described in the following paragraphs with reference to FIGS. 3A-3C.

Reference is now made to FIG. 3A. FIG. 3A is a schematic diagram of an example of a cell group of the bit cells 101 in FIGS. 1 and 2A-2B in a top view, in accordance with some embodiments of the present disclosure. With respect to the embodiments of FIGS. 1 and 2A-2B, like elements in FIG. 3A are designated with the same annotations and/or reference numbers for ease of understanding.

For illustration, a cell group includes two bit cells 101 annotated as bit cell CA and bit cell CB. The bit cell CA and the bit cell CB are bit cells 101 in a same column. The bit cell CA and the bit cell CB are bit cells 101 in different rows. For example, the bit cell CA is a bit cell 101 in the row R1 and the bit cell CB is a bit cell 1001 in the row R2.

As shown in FIG. 3A, the boundary BDY is the boundary of the cell group (the bit cell CA and the bit cell CB). The bit cell CA and the cel-2 are arranged next to each other along a direction x. The word lines WL extend along the direction x. The bit lines BL and BLB extend along a direction y. The direction x is perpendicular to the direction y.

The dots in FIG. 3A denote where the word lines and the bit lines are coupled to the bit cells CA and CB. The word line WL of the row (e.g., row R1) of the bit cell CA is coupled to the bit cell CA at a first side of the boundary BDY. The word line WL of the row (e.g., row R2) of the bit cell CB is coupled to the bit cell CB at a second side of the boundary BDY. The first side is opposite to the second side.

The bit line BL of the column (e.g., column C1) of the bit cell CA and bit cell CB is coupled to the bit cell CA at a third side of the boundary BDY. The bit line BLB of the column (e.g., column C1) of the bit cell CA and bit cell CB is coupled to the bit cell CB at a fourth side of the boundary BDY. The third side is opposite to the fourth side.

According to some embodiments of the present disclosure, the bit line BL is further coupled to the bit cell CB. The bit line BLB is further coupled to the bit cell CA. Alternatively speaking, the bit cell CA and the bit cell CB share the bit line BL and the bit line BLB.

Reference is now made to FIG. 3B. FIG. 3B is a schematic diagram of a memory device 300a configured with respect to the memory device 100 including cell groups corresponding to FIGS. 1, 2A-2B and 3A in a top view, in accordance with some embodiments of the present disclosure. With respect to the embodiments of FIGS. 1, 2A-2B and 3A, like elements in FIG. 3B are designated with the same annotations and/or reference numbers for ease of understanding.

For illustration, the word lines WL1-WLm denote the word lines WL of the rows R1-Rm, respectively. As shown in FIG. 3B, the word lines WL1-WLm of the memory device 100 extend along the direction x and are separated from each other along the direction y.

On the contrary, the pairs of bit line BL and BLB extend along the direction y and are separated from each other along the direction x.

As shown in FIG. 3B, every two word lines WL, the arrangement order of the odd word line WL and the even word line WL along the direction y is altered. For example, the word lines WL1-WLm are arranged in the order of “WL1, WL2, WL4, WL3, WL5, WL6, WL8, WL7 . . . ” along the direction y.

In some embodiments, the bit cells 101 of the memory device 100 are arranged into cell groups described previously with reference to FIG. 3A. The cell groups corresponding to two same rows are arranged adjacently one after another along the direction x. The cell groups corresponding to a same column are arranged adjacently one after another along the direction y.

In some embodiments, the bit cell CA corresponds to an odd row. For example, the word line WL1 is coupled to the bit cells CA of the cell groups corresponding to the rows R1-R2. On the contrary, the bit cell CB corresponds to an even row. For example, the word line WL2 is coupled to the bit cells CB of the cell groups corresponding to the rows R1-R2.

In some embodiments, a cell group and its adjacent cell group along the direction x or the direction y are mirrored to each other about the boundary line between them. For example, a cell group G11 is mirrored to a cell group G12 about the boundary line between them. Similarly, the cell group G11 is mirrored to a cell group G21 about the boundary line between them.

Reference is now made to FIG. 3C. FIG. 3C is a schematic diagram of a memory device 300b configured with respect to the memory devices 100 and the memory device 300a corresponding to FIGS. 1, 2A-2B and 3A in a top view, in accordance with some embodiments of the present disclosure. With respect to the embodiments of FIGS. 1, 2A-2B and 3A-3B, like elements in FIG. 3C are designated with the same annotations and/or reference numbers for ease of understanding.

The difference between the memory devices 300a and 300b is that, the order of the word lines WL1-WLm along the direction y corresponds to the row numbers of the word lines WL1-WLm. For example, the word lines WL1-WLm are arranged in the order of “WL1, WL2, WL3, WL4, WL5, WL6, WL7, WL8 . . . ” along the direction y.

In a cell group (e.g., cell group G11) of an odd physical row of cell groups, the bit cell CA is coupled to the word line WL of an odd memory address row (e.g., the row R1). The bit cell CB is coupled to the word line WL of an even memory address row (e.g., the row R2).

On the contrary, in a cell group (e.g., cell group G21) of an even physical row of cell groups, the bit cell CA is coupled to the word line WL of an even memory address row (e.g., the row R4). The bit cell CB is coupled to the word line WL of an odd memory address row (e.g., the row R3).

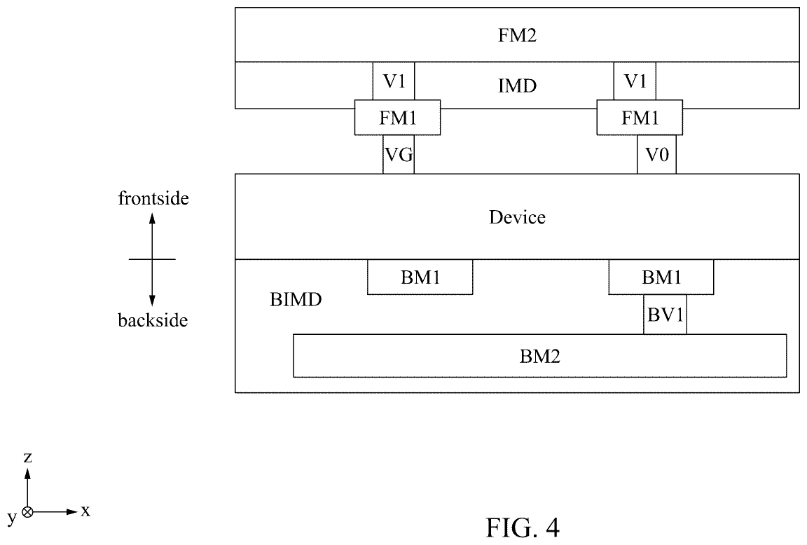

In some embodiments, the memory device 100 is referred to as an integrated circuit structure including active semiconductor device s (i.e., with drain/source structure implement ed with active areas, gate structures, metal-on-device (MD) corresponding to contacts and backside contacts on the active areas, etc.) and front side metal routing on its front side and some metal routing on its backside. In some embodiments, the active semiconductor device on the front side of the memory device 100 is formed on a substrate in a front side process. After the front side process is complete, the memory device 100 is flipped upside down, such that a backside surface of the substrate faces upwards. The substrate is further thinned down and removed. In some embodiments, thinning is accomplished by a chemical mechanical planarization (CMP) process, a grinding process, or the like. Accordingly, backside process is performed to form structures on the backside of the memory device 100. Further detail about layers of the memory device 100 is described in the following paragraphs with reference to FIG. 4.

Reference is now made to FIG. 4. FIG. 4 is a schematic diagram of an example of layers of the memory device 100 of FIGS. 1, 2A-2B and 3A-3C in accordance with some embodiments of the present disclosure. With respect to the embodiments of FIGS. 1, 2A-2B and 3A-3C, like elements in FIG. 4 are designated with the same annotations and/or reference numbers for ease of understanding.

For illustration, the front side of the memory device 100 includes a device layer, a source/drain (S/D) via-0 layer (V0), a gate via layer (VG), a front side metal one layer (FM1), a via-1 layer (V1), a front side metal two layer (FM2) stacked along a direction z.

The device layer includes gates, an oxide diffusion (OD) layer of active areas corresponding to source/drain terminals and channels, contacts and backside contacts of MD.

As shown in FIG. 4, the gate via layer and the S/D via-0 layer are above the device layer. The front side metal one layer is above the gate via layer and the S/D via-0 layer. In some embodiments, the vias of the gate via layer are configured to couple gates to the metal lines in the front side metal one layer. The vias of the S/D via-0 layer are configured to couple active areas to the metal lines in the front side metal one layer.

The via-1 layer is above the front side metal one layer. The front side metal two layer is above the via-1 layer. Vias in the via-1 layer are configured to couple the metal lines in the front side metal one layer to the metal lines in the front side metal two layer.

The backside of the memory device 100 includes a backside metal one layer (BM1), a backside via-1 layer (BV1) and a backside metal two layer (BM2).

The backside metal one layer is below the device layer. In some embodiments, the metal lines in the backside metal one layer are coupled to the backside contacts.

The backside via-1 layer is below the backside metal one layer. The backside metal two layer is below the backside via-1 layer. The vias in the backside via-1 layer are configured to couple the metal lines in the backside metal one layer to the metal lines in the backside metal two layer.

In some embodiments, the front side metal layers are separated from each other by inter-metal-dielectric (IMD). The backside metal layers are separated from each other by back inter-metal-dielectric (BIMD). In some embodiments, the material of the IMD and the BIMD are different.

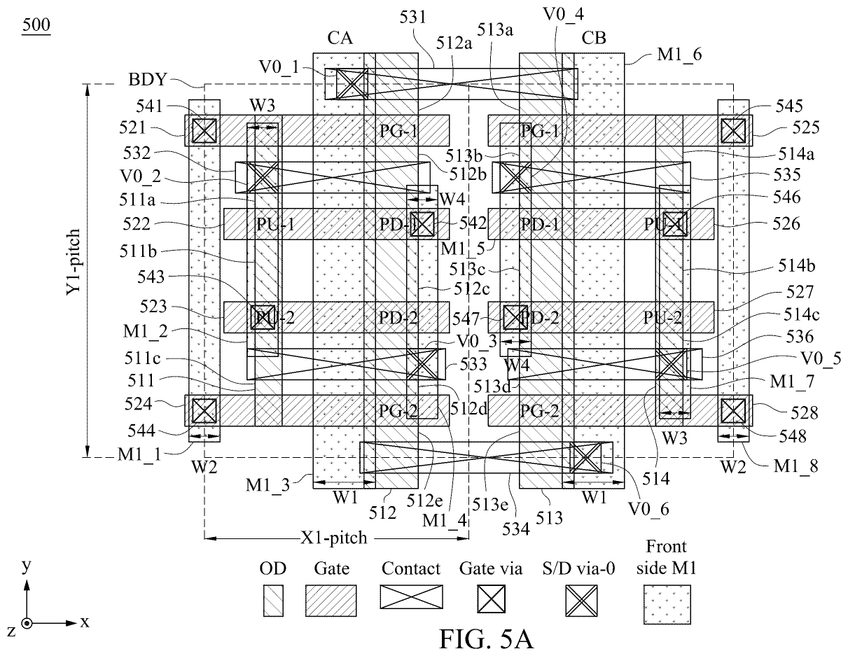

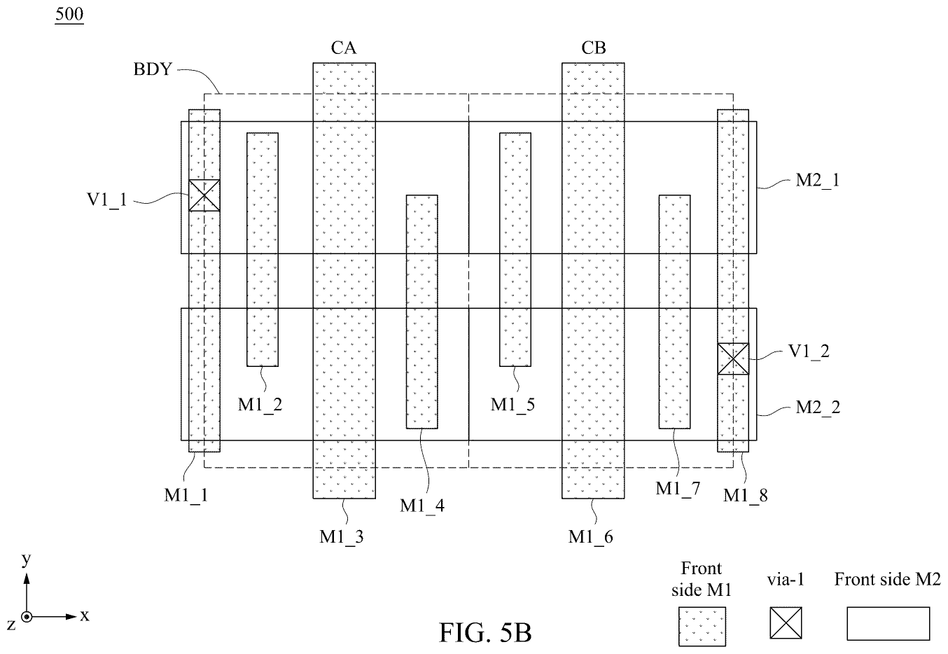

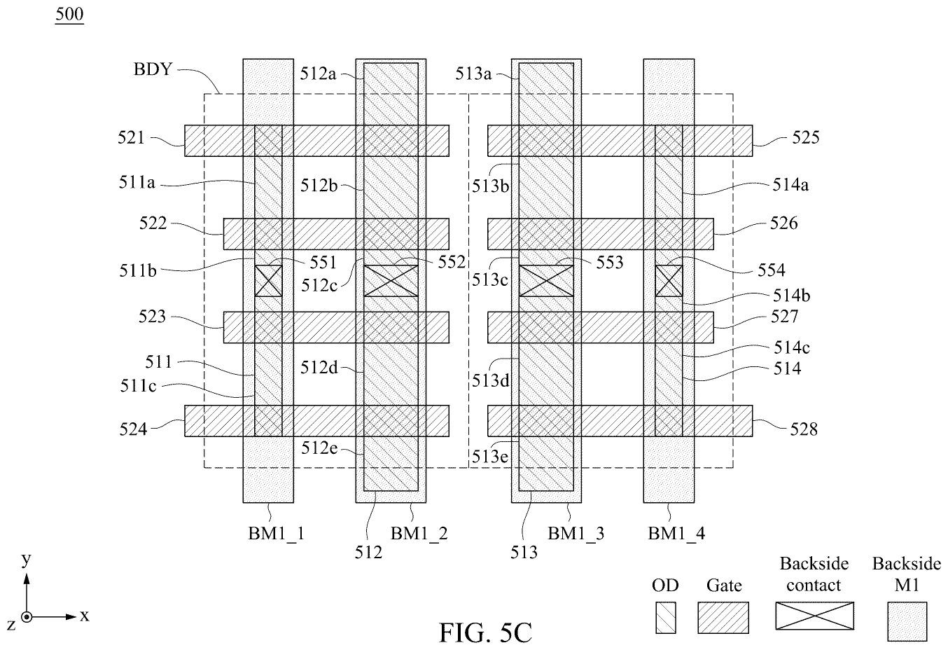

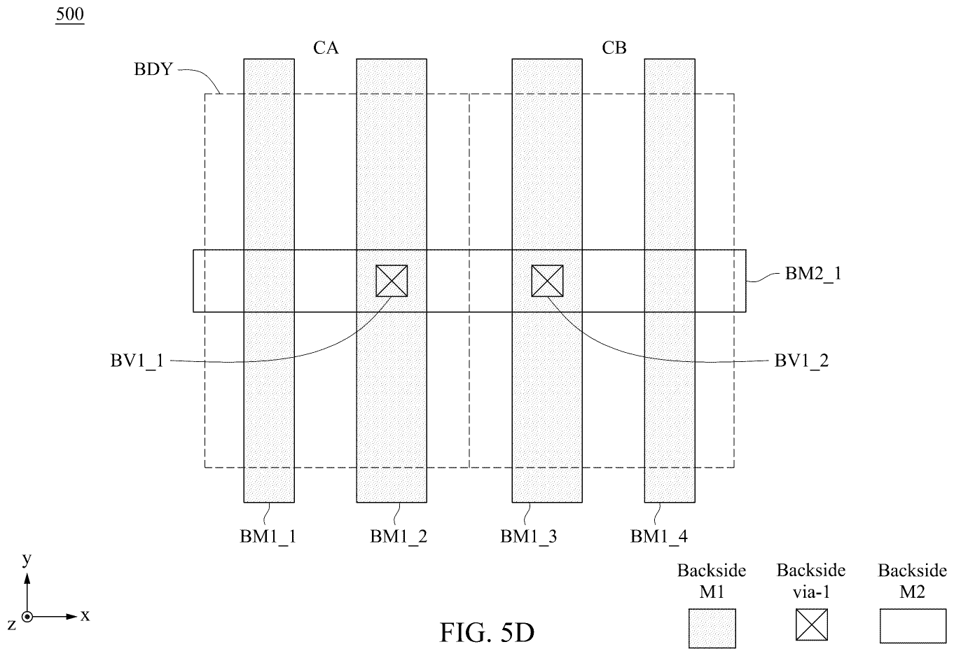

In the following paragraphs, examples of semiconductor layout of front side and backside of cell group corresponding to the memory devices 100, 300a and 300b are described with reference to FIGS. 5A-5D and 6-10.

Reference is now made to FIGS. 5A-5D. FIGS. 5A-5B are layout diagrams of front side of a cell group 500 configured with respect to the cell groups corresponding to the memory devices 100, 300a and 300b of FIGS. 1, 2A-2B, 3A-3C and 4, in accordance with some embodiments of the present disclosure. FIGS. 5C-5D are layout diagrams of backside of the cell group 500, in accordance with some embodiments of the present disclosure. With respect to the embodiments of FIGS. 1, 2A-2B, 3A-3C and 4, like elements in FIGS. 5A-5D are designated with the same annotations and/or reference numbers for ease of understanding.

For illustration, the cell group 500 includes metal lines M1_1-M1_8, contacts 531, 534 and the bit cells CA and CB. The bit cell CA includes active areas 511-512, gates 521-524, contacts 532-533, gate vias 541-544, vias V0_1, V0_2, V0_3. The bit cell CB includes active areas 513-514, gates 525-528, contacts 535-5336, gate vias 545-548, vias V0_4, V0_5, V0_6.

The active areas 511-514 are active areas extending along the direction y in the OD layer. The gates 521-524 extends along the direction x across the active areas 511-512. The active area 511 includes active regions 511a-511c. The active area 512 includes active regions 512a-512e.

The active regions 511a-511c, 512a-512e, gates 521-524 correspond to the transistors PG-1, PU-1, PD-1, PU-2, PD-2 and PG-2 of the bit cell CA.

Specifically, the gate 521 corresponds to the gate terminal of the transistor PG-1. The active region 512a corresponds to the source/drain terminal of the transistor PG-1. The active region 512b corresponds to the drain/source terminal of the transistor PG-1.

The gate 522 corresponds to the gates terminals of the transistor PU-1 and PD-1. The active region 511a corresponds to the drain/source terminal of the transistor PU-1. The active region 511b corresponds to the source/drain terminal of the transistor PU-1. The active region 512b corresponds to the drain source terminal of the transistor PD-1. The active region 512c corresponds to the source/drain terminal of the transistor PD-1.

The gate 523 corresponds to the gates terminals of the transistor PU-2 and PD-2. The active region 511c corresponds to the drain/source terminal of the transistor PU-2. The active region 511b further corresponds to the source/drain terminal of the transistor PU-2. The active region 512d corresponds to the drain source terminal of the transistor PD-2. The active region 512c further corresponds to the source/drain terminal of the transistor PD-2.

The gate 524 corresponds to the gate terminal of the transistor PG-2. The active region 512d further corresponds to the drain/source terminal of the transistor PG-2. The active region 512e corresponds to the source/drain terminal of the transistor PG-2.

The gates 525-528 extends along the direction x across the active areas 513-514. The active area 513 includes active regions 513a-513e. The active area 514 includes active regions 514a-514c.

The active regions 513a-513e, 514a-514c, gates 525-528 correspond to the transistors PG-1, PU-1, PD-1, PU-2, PD-2 and PG-2 of the bit cell CB.

Specifically, the gate 525 corresponds to the gate terminal of the transistor PG-1. The active region 513a corresponds to the source/drain terminal of the transistor PG-1. The active region 513b corresponds to the drain/source terminal of the transistor PG-1.

The gate 526 corresponds to the gates terminals of the transistor PU-1 and PD-1. The active region 514a corresponds to the drain/source terminal of the transistor PU-1. The active region 514b corresponds to the source/drain terminal of the transistor PU-1. The active region 513b corresponds to the drain source terminal of the transistor PD-1. The active region 513c corresponds to the source/drain terminal of the transistor PD-1.

The gate 527 corresponds to the gates terminals of the transistor PU-2 and PD-2. The active region 514c corresponds to the drain/source terminal of the transistor PU-2. The active region 514b further corresponds to the source/drain terminal of the transistor PU-2. The active region 513d corresponds to the drain source terminal of the transistor PD-2. The active region 513c further corresponds to the source/drain terminal of the transistor PD-2.

The gate 528 corresponds to the gate terminal of the transistor PG-2. The active region 513d further corresponds to the drain/source terminal of the transistor PG-2. The active region 513e corresponds to the source/drain terminal of the transistor PG-2.

The contacts 531-536 are contacts extending along the direction x in the contact layer between the OD layer and the S/D via-0 layer. The vias V0_1-V0_6 are vias in the S/D via-0 layer. The metal lines M1_1-M1_8 are metal lines in the front side metal one layer. The gate vias 541-548 are vias of the gate via layer.

The contact 531 extends to connect the active region 512a and 513a. The via V0_1 connects the contact 531 and the metal line M1_3. In some embodiments, the metal line M1_3 corresponds to the bit line BL.

The contact 532 extends to connect the active regions 511a and 512b. The via V0_2 connects the contact 532 and the metal line M1_2. The gate via 543 connects the metal line M1_2 and the gate 523. The contact 532, the via V0_2, the metal line M1_2 and the gate via 543 are coupled together as the node N1 of the bit cell CA.

The contact 533 extends to connect the active regions 511c and 512d. The via V0_3 connects the contact 533 and the metal line M1_4. The gate via 542 connects the metal line M1_4 and the gate 522. The contact 533, the via V0_3, the metal line M1_4 and the gate via 542 are coupled together as the node N2 of the bit cell CA.

The contact 534 extends to connect the active region 512e and 513e. The via V0_6 connects the contact 534 and the metal line M1_6. In some embodiments, the metal line M1_6 corresponds to the bit line BLB.

As shown in FIG. 5A, the bit cells CA and CB share a bit line BL and a bit line BLB (metal lines M1_3 and M1_6). A bit cell area includes only one bit line (bit line BL or BLB). For example, there is only the bit line BL (metal line M1_3) within the boundary of the bit cell CA.

In some embodiments, the metal line M1_3 of a cell group 500 extends to contact the metal lines M1_3 of adjacent cell groups 500 in a same column along the direction y to form the bit line BL of the column.

Similarly, the metal line M1_6 of a cell group 500 extends to contact the metal lines M1_6 of adjacent cell groups 500 in a same column along the direction y to form the bit line BLB of the column.

In some embodiments, the metal lines of bit lines BL and BLB have greatest width among the metal lines in the front side metal one layer. For example, the width W1 of the metal lines M1_3, M1_6 is wider than the widths W2-W4 of other metal lines. In some embodiments, the ratio of the width W1 to the widths W2-W4 is about 1.5 to 5.

The Y1-pitch in FIG. 5A denotes the length of a bit cell 101 (bit cell CA or bit cell CB) along the direction y. The X1-pitch in FIG. 5A denotes the width of a bit cell 101 (bit cell CA or bit cell CB) along the direction X. The Y1-pitch is four times contacted poly pitch (CPP). The X1-pitch of the bit cell 101 (bit cell CA or bit cell CB) is smaller than the X1-pitch of some approaches. In some embodiments, the X1-pitch of the bit cell 101 is configured as a minimum width for two OD lines (e.g., active areas 511 and 512).

In some embodiments, the Y1-pitch is greater than the X1-pitch. The ratio of the Y1 pitch to the X1 pitch is about 1.2 to 2.5.

The contact 535 extends to connect the active regions 513b and 514a. The via V0_4 connects the contact 535 and the metal line M1_5. The gate via 547 connects the metal line M1_5 and the gate 527. The contact 535, the via V0_4, the metal line M1_5 and the gate via 547 are coupled together as the node N1 of the bit cell CB.

The contact 536 extends to connect the active regions 513d and 514c. The via V0_5 connects the contact 536 and the metal line M1_7. The gate via 546 connects the metal line M1_7 and the gate 526. The contact 536, the via V0_5, the metal line M1_7 and the gate via 546 are coupled together as the node N2 of the bit cell CB.

The gate via 541 connects the gate 521 and the metal line M1_1. The gate via 544 connects the gate 524 and the metal line M1_1. In some embodiments, the metal line M1_1 is configured as a landing line of the word line WL of the bit cell CA.

Similarly, the gate via 545 connects the gate 525 and the metal line M1_8. The gate via 548 connects the gate 528 and the metal line M1_8. In some embodiments, the metal line M1_8 is configured as a landing line of the word line WL of the bit cell CB.

As shown in FIG. 5B, the cell group 500 further includes vias V1_1, V1_2, metal lines M2_1, M2_2. The vias V1_1, V1_2 are vias in the via-1 layer. The metal lines M2_1, M2_2 are metal lines in the front side metal two layer.

The via V1_1 connects the metal line M1_1 and the metal line M2_1. The via V1_2 connects the metal line M1_8 and the metal line M2_2. In some embodiments, the metal line M2_1 is configured as the word line WL of the bit cell CA. The metal line M2_2 is configured as the word line WL of the bit cell CB.

In some embodiments, the metal line M2_1 of a cell group 500 extends to contact the metal lines M2_1 of adjacent cell groups 500 in a same row along the direction x to form the word line WL of the row.

Similarly, the metal line M2_1 of a cell group 500 extends to contact the metal lines M2_1 of adjacent cell groups 500 in a same row along the direction x to form the word line WL of the row.

As shown in FIG. 5C, the cell group 500 further includes backside contacts 551-554 and metal lines BM1_1-BM1_2. The backside contacts 531-536 are contacts in the backside contact layer between the OD layer and the backside metal one layer. The backside metal lines BM1_1-BM1_4 are metal lines in the backside metal one layer.

The backside contact 551 connects the active region 511b to the metal line BM1_1 The backside contact 552 connects the active region 512c to the metal line BM1_2. The backside contact 553 connects the active region 513c to the metal line BM1_3. The backside contact 554 connects the active region 514b to the metal line BM1_4.

In some embodiments, the metal lines BM1_1 and BM1_4 are configured as power rails for transmitting the supply voltage VDD. The metal lines BM1_2 and BM1_3 are configured as power rails for transmitting the supply voltage VSS.

Compared with some approaches, in the cell group 500, the conductors (e.g., metal lines BM1_1-BM1_4) are arranged to the backside of the memory device to reduce the routing loading of the front side and the bit cell size (e.g., bit cell 101) can be reduced as well. Less metal lines in a same layer benefits the metal conductor RC performance (lower resistance and/or lower capacitance).

In some embodiments, the metal lines BM1_1-BM1_4 of a cell group 500 extend to contact the metal lines BM1_1-BM1_4, respectively, of adjacent cell groups 500 in a same column along the direction y to form power rails of the column.

As shown in FIG. 5D, the cell group 500 further includes vias BV1_1, BV1_2 and a metal line BM2_1. The vias BV1_1, BV1_2 are vias in the backside via-1 layer. The metal line BM2_1 is a metal line in the backside metal two layer.

The via BV1_1 connects the metal line BM1_2 and the metal line BM2_1. The via BV1_2 connects the metal line BM1_3 and the metal line BM2_1. In some embodiments, the metal lines BM1_2, BM1_3 and the BM2_1 are coupled together to form a power mesh for the robustness of providing supply voltage VSS.

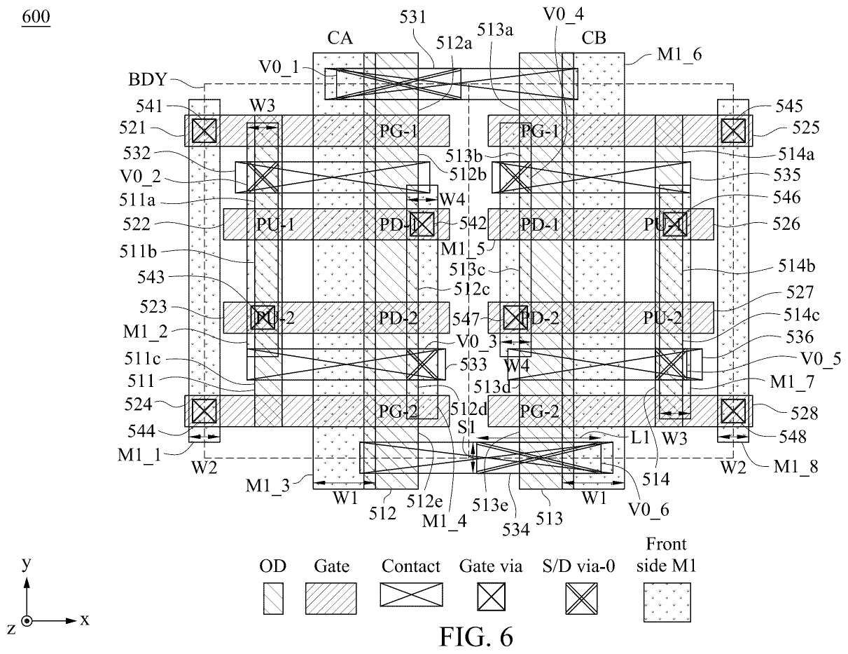

Reference is now made to FIG. 6. FIG. 6 is layout diagram of front side of a cell group 600 configured with respect to the cell group 500 of FIGS. 5A-5D and the cell groups corresponding to the memory devices 100, 300a and 300b of FIGS. 1, 2A-2B, 3A-3C and 4, in accordance with some embodiments of the present disclosure. With respect to the embodiments of FIGS. 1, 2A-2B, 3A-3C, 4 and 5A-5D, like elements in FIG. 6 are designated with the same annotations and/or reference numbers for ease of understanding.

Compared with the vias via0_1, V0_6 of the cell group 500, the vias V0_1, V0_6 of the cell group 600 have longer shape. The vias V0_1, V0_6 having longer shape with more area coupled to the contacts 531, 534 reduce the resistance and improve the robustness.

The longer vias V0_1, V0_6 also help reduce the difference between the resistance from the bit lines to the bit cell CA and the resistance from the bit lines to the bit cell CB.

In some embodiments, for the vias V0_1, V0_6 of the cell group 600, the ratio of the length L1 along the direction x to the width S1 along the direction is about 2 to 5.

In some embodiments, the vias via0_1, V0_6 are partially cover by the bit line BL and BLB. For, example, the vias via0_1 is partially covered by the metal line M1_3.

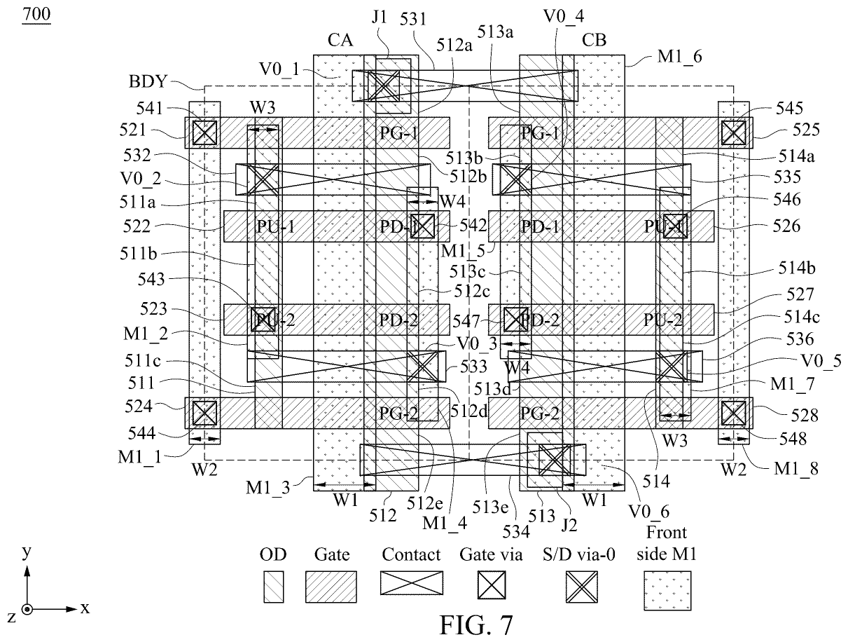

Reference is now made to FIG. 7. FIG. 7 is layout diagram of front side of a cell group 700 configured with respect to the cell group 500 of FIGS. 5A-5D and the cell groups corresponding to the memory devices 100, 300a and 300b of FIGS. 1, 2A-2B, 3A-3C and 4, in accordance with some embodiments of the present disclosure. With respect to the embodiments of FIGS. 1, 2A-2B, 3A-3C, 4 and 5A-5D, like elements in FIG. 7 are designated with the same annotations and/or reference numbers for ease of understanding.

The difference between the cell group 500 and the cell group 700 is that the cell group 700 further includes extension jogs J1 and J2. The extension jogs J1 and J2 are metal in the front side metal one layer. The extension jog J1 extends from the metal line M1_3 along the direction x. The extension jog J1 is coupled between the contact 531 and the via V0_1. Similarly, the extension jog J2 extends from the metal line M1_6 along the direction x. The extension jog J2 is coupled between the contact 534 and the via V0_6.

Compared with the vias V0_1, V0_6 of the cell group 500, the vias V0_1, V0_6 of the cell group 700 are arranged closer to the active areas 512, 513. In some embodiments, a first portion of the via V0_1 is below the metal line M1_3 and a second portion of the via V0_1 is below the extension jog J1. A first portion of the via V0_6 is below the metal line M1_6 and a second portion of the via v0_6 is below the extension jog J2 as shown in FIG. 7.

The extension jogs J1, J2 and the vias V0_1, V0_6 being closer to the active areas 512, 513 help reduce the resistance between the active areas 512, 513 and the metal lines M1-3 and M1_6.

The vias V0_1, V0_6 are also closer to the center line between the bit cells CA and CB. In this way, the resistance between the bit lines and the bit cell CA and the resistance between the bit lines and the bit cell CB are closer.

In some embodiments, the contacts 531, 534 of the cell group 700 is shorter than the he contacts 531, 534 of the cell group 500. The shorter contacts 531, 534 help reduce the gate-to-contact capacitance which is a parasitic capacitance between gate and contact (e.g., contact 531 and gate 511).

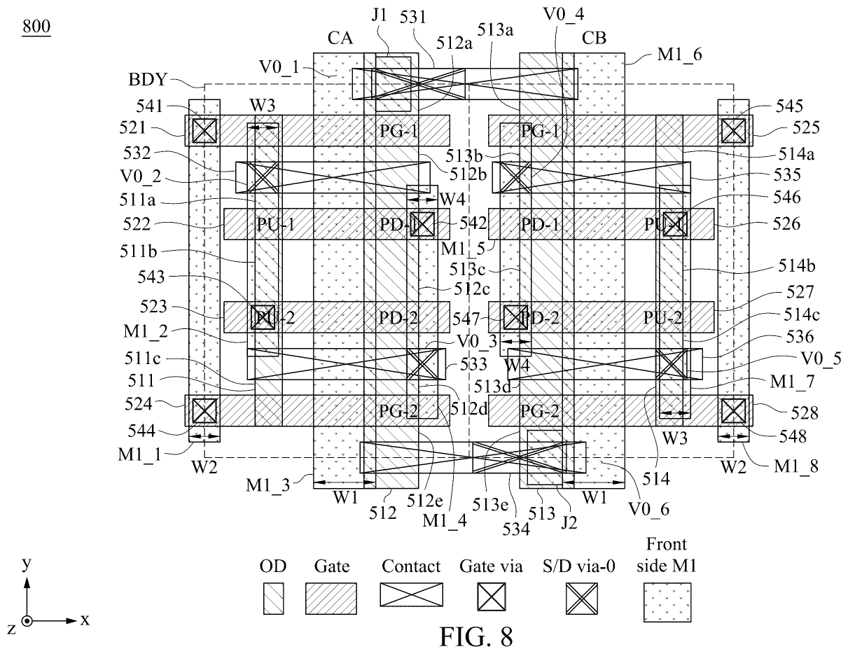

Reference is now made to FIG. 8. FIG. 8 is layout diagram of front side of a cell group 800 configured with respect to the cell group 700 of FIG. 7, the cell group 500 of FIGS. 5A-5D and the cell groups corresponding to the memory devices 100, 300a and 300b of FIGS. 1, 2A-2B, 3A-3C and 4, in accordance with some embodiments of the present disclosure. With respect to the embodiments of FIGS. 1, 2A-2B, 3A-3C, 4, 5A-5D and 7, like elements in FIG. 8 are designated with the same annotations and/or reference numbers for ease of understanding.

Compared with the vias V0_1, V0_6 of the cell group 700, the vias V0_1, V0_6 of the cell group 800 have longer shape. In some embodiments, for the vias V0_1, V0_6 of the cell group 600, the ratio of the length L1 along the direction x to the width S1 along the direction is about 2 to 5.

As shown in FIG. 8, in some embodiments, the vias V0_1, V0_6 are partially covered by the extension jogs J1 and J2. For example, there is no metal of the front side metal one layer above a portion of the vias V0_1.

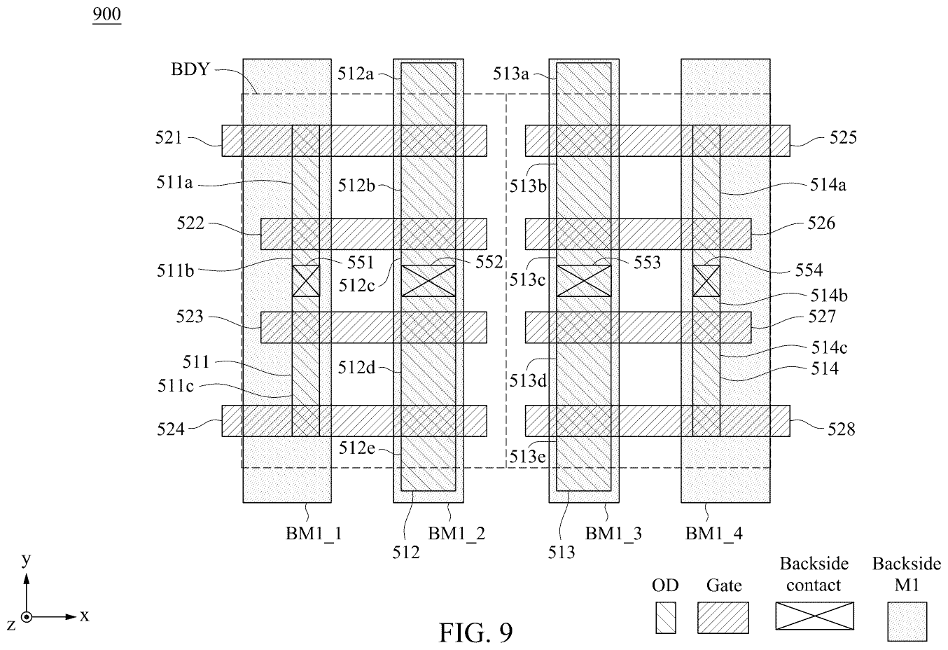

Reference is now made to FIG. 9. FIG. 9 is layout diagram of backside of a cell group 900 configured with respect to the cell groups 500, 600, 700, 800 of FIGS. 5A-5D, 6-8 and the cell groups corresponding to the memory devices 100, 300a and 300b of FIGS. 1, 2A-2B, 3A-3C and 4, in accordance with some embodiments of the present disclosure. With respect to the embodiments of FIGS. 1, 2A-2B, 3A-3C, 4 ,5A-5D and 6-8, like elements in FIG. 9 are designated with the same annotations and/or reference numbers for ease of understanding.

Compared with the metal lines BM1_1, BM1_4 of the cell groups 500, 600, 700 and 800, the metal lines BM1_1, BM1_4 of the cell group 900 have greater width along the direction x. The metal lines BM1_1, BM1_4 of the cell group 900 are wide enough to be aligned with the boundary BDY. The metal line BM1_1 of a cell group 900 contact the metal line BM1_1 of an adjacent cell group 900 along the direction x to form a shared power rail. Similarly, the metal line BM1_4 of the cell group 900 contact the metal line BM1_4 of another adjacent cell group 900 in the other side along the direction x to form another shared power rail.

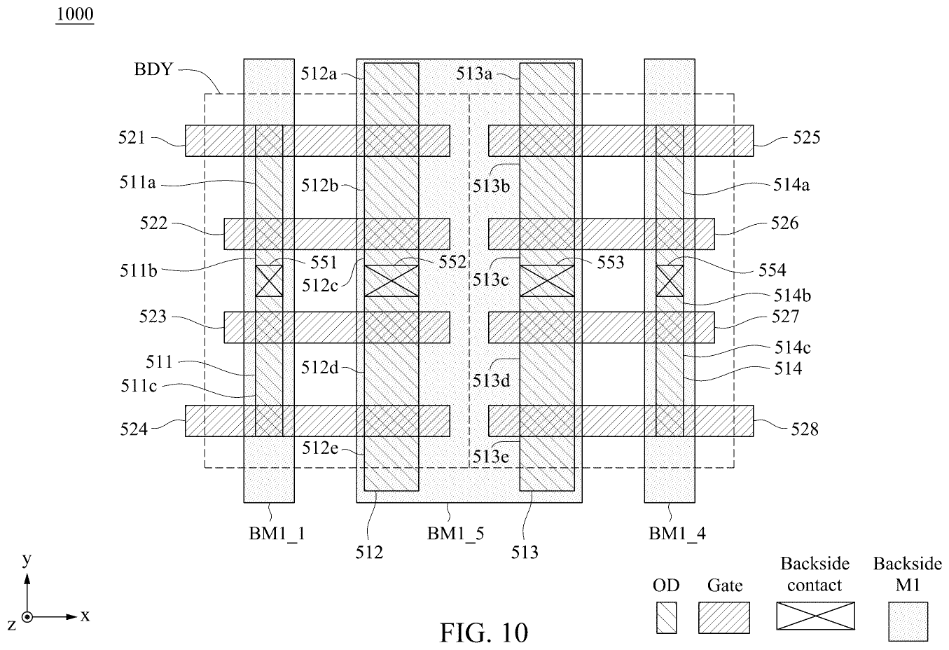

Reference is now made to FIG. 10. FIG. 10 is layout diagram of backside of a cell group 1000 configured with respect to the cell groups 500, 600, 700, 800, 900 of FIGS. 5A-5D, 6-9 and the cell groups corresponding to the memory devices 100, 300a and 300b of FIGS. 1, 2A-2B, 3A-3C and 4, in accordance with some embodiments of the present disclosure. With respect to the embodiments of FIGS. 1, 2A-2B, 3A-3C, 4, 5A-5D and 6-9, like elements in FIG. 10 are designated with the same annotations and/or reference numbers for ease of understanding.

Compared with the metal lines BM1_2, BM1_3 of the cell groups 500, 600, 700, 800 and 900, the metal lines BM1_2, BM1_3 of the cell group 1000 have a metal line BM1_5 instead of the metal lines BM1_2, BM1_3. The metal line BM1_5 is a metal line extending along the direction y in the backside metal one layer. The metal line BM1_5 is coupled to the backside contacts 552 and 553 to transmit the supply voltage VSS. The wider metal lines for supply voltages help lower resistance to improve transmitting speed and chip power IR drop is reduced.

The configurations of FIGS. 1, 2A-2B, 3A-3C, 4, 5A-5D, 6-10 are given for illustrative purposes. Various implements are within the contemplated scope of the present disclosure. For example, in some embodiments, a cell group may have the metal lines BM1_1, BM1_4 shown in FIG. 9 and the metal line BM1_5 shown in FIG. 10.

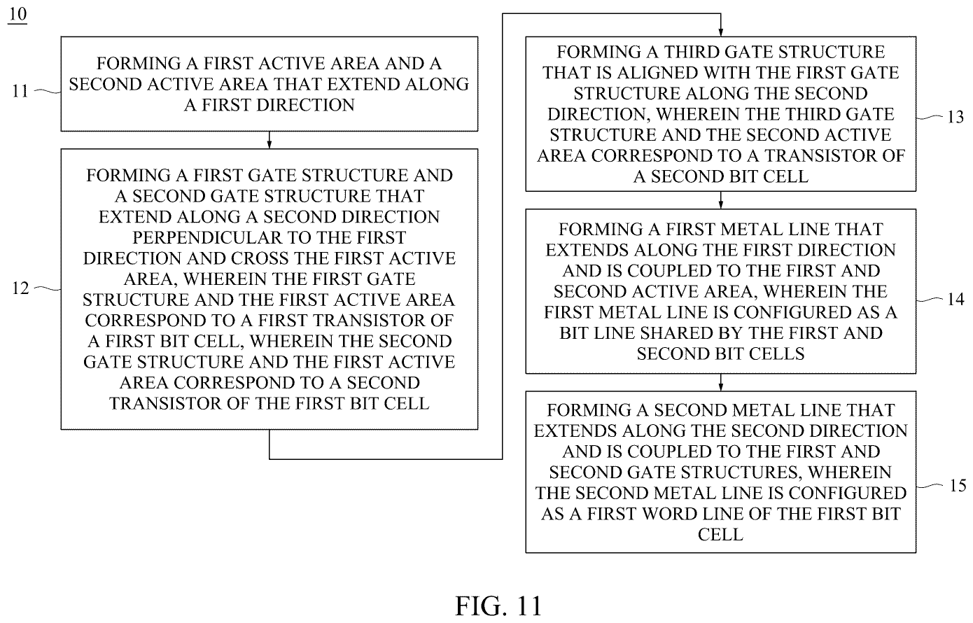

Reference is now made to FIG. 11. FIG. 11 is a flowchart diagram of a method 10 for manufacturing the memory devices 100, 300a-300b, bit cell 101, cell groups 500-1000 as shown in FIGS. 1, 2A-2B, 3A-3C, 4, 5A-5D, 6-10, in accordance with some embodiments of the present disclosure. It is understood that additional steps can be provided before, during, and after the steps shown by FIG. 11, and some of the steps described below can be replaced or eliminated, for additional embodiments of the method. The order of the steps may be interchangeable. Some of the steps are performed concurrently. Throughout the various views and illustrative embodiments, like annotations and reference numbers are used to designate like elements. The method 10 includes steps 11-15 that are described below with reference to the memory devices 100, 300a-300b, bit cell 101, cell groups 500-1000 corresponding to FIGS. 1, 2A-2B, 3A-3C, 4, 5A-5D, 6-10.

In step 11, the active areas 511-514 extending along the direction y are formed.

In step 12, the gate structures 521-524 extending along the direction x are formed. The active areas 511-512 and the gate structures 521-524 correspond to transistors in the bit cell CA. For example, the active area 512 and the gate structure 521 correspond to the transistor PG-1. The active area 512 and the gate structure 524 correspond to the transistor PG-2.

In step 13, the gate structures 525-528 aligned with the gate structures 521-524 respectively along the direction x are formed. The active areas 513-514 and the gate structures 525-528 correspond to transistors in the bit cell CB. For example, the active area 513 and the gate structure 525 correspond to the transistor PG-1 of the bit cell CB.

In step 15, the metal lines M1_1-M1_8 extending along the direction y in the front side metal one layer are formed. The metal line M1_3 is coupled to the active areas 512-513 and is configured as the bit line BL shared by the bit cells CA and CB. Similarly, the metal line M1_6 is coupled to the active areas 512-513 and is configured as the bit line BLB shared by the bit cells CA and CB.

In step 16, the metal lines M2_1-M2_2 extending along the direction x are formed. The metal lines M2_1 is coupled to the gate structures 521 and 524 and is configured as the word line WL of the bit cell CA. Similarly, the metal lines M2_2 is coupled to the gate structures 525 and 528 and is configured as the word line WL of the bit cell CB.

In some embodiments, the method 10 further comprises: forming the front side via-0 layer. For example, the via V0_1 is formed. The via V0_1 is coupled between the metal line M1_3 and the active area 512. In some embodiments, the length L1 of the via V0_1 is greater than the width S1 of the via V0_1. In some embodiments, the via V0_1 is partially under the metal line M1_3.

In some embodiments, the method 10 further comprises: forming the backside metal layers. For example, the metal line BM1_2 is formed at the backside. The metal line BM1_2 is coupled to the active area 512 and is configured to transmit the supply voltage VSS.

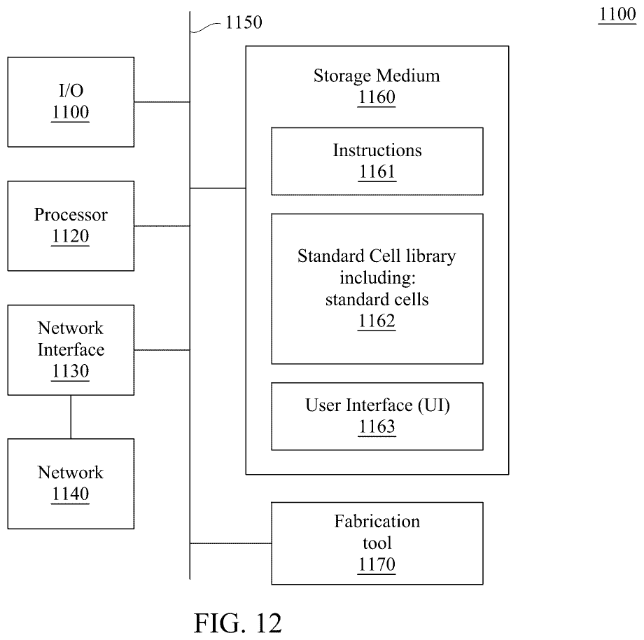

Reference is now made to FIG. 12. FIG. 12 is a block diagram of an electronic design automation (EDA) system 1100 for designing the integrated circuit layout design, in accordance with some embodiments of the present disclosure. The EDA system 1100 is configured to implement one or more steps of the method 10 disclosed in FIG. 11, and layout design disclosed in FIGS. 5A-5D, 6-10.

In some embodiments, the EDA system 1100 is a general purpose computing device including a hardware processor 1120 and a non-transitory, computer-readable storage medium 1160. The storage medium 1160, amongst other things, is encoded with, i.e., stores, instructions (computer program code) 1161, i.e., a set of executable instructions. Execution of the instructions 1161 by hardware processor 1120 represents (at least in part) an EDA tool which implements a portion or all of, e.g., the method 1000, and method for implementing layout design disclosed in FIGS. 5A-5D, 6-10.

The processor 1120 is electrically coupled to the storage medium 1160 via a bus 1150. The processor 1120 is also electrically coupled to an input/output (I/O) interface 1110 and a fabrication tool 1170 by bus 1150. A network interface 1130 is also electrically connected to processor 1120 via bus 1150. Network interface 1130 is connected to a network 1140, so that processor 1120 and the storage medium 1160 are capable of connecting to external elements via the network 1140. The processor 1120 is configured to execute the instructions 1161 encoded in the storage medium 1160 in order to cause the EDA system 1100 to be usable for performing a portion or all of the noted processes and/or methods. In one or more embodiments, the processor 1120 is a central processing unit (CPU), a multi-processor, a distributed processing system, an application specific integrated circuit (ASIC), and/or a suitable processing unit.

In one or more embodiments, the storage medium 1160 is an electronic, magnetic, optical, electromagnetic, infrared, and/or a semiconductor system (or apparatus or device). For example, the storage medium 1160 includes a semiconductor or solid-state memory, a magnetic tape, a removable computer diskette, a random access memory (RAM), a read-only memory (ROM), a rigid magnetic disk, and/or an optical disk. In one or more embodiments using optical disks, the storage medium 1160 includes a compact disk-read only memory (CD-ROM), a compact disk-read/write (CD-R/W), and/or a digital video disc (DVD).

In one or more embodiments, the storage medium 1160 stores the instructions 1161 configured to cause the EDA system 1100 (where such execution represents (at least in part) the EDA tool) to be usable for performing a portion or all of the noted processes and/or methods. In one or more embodiments, the storage medium 1160 also stores information which facilitates performing a portion or all of the noted processes and/or methods. In one or more embodiments, storage medium 1160 stores library 1162 of standard cells including such standard cells as disclosed herein, for example, bit cells disclosed in FIGS. 2A-2B, 3A-3C, 5A-5D and 6-10.

The EDA system 1100 includes the I/O interface 1110. The I/O interface 1110 is coupled to external circuitry. In one or more embodiments, the I/O interface 1110 includes a keyboard, keypad, mouse, trackball, trackpad, touchscreen, and/or cursor direction keys for communicating information and commands to the processor 1120.

EDA system 1100 also includes the network interface 1130 coupled to processor 1120. The network interface 1130 allows the EDA system 1100 to communicate with the network 1140, to which one or more other computer systems are connected. The network interface 1130 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 1100.

The EDA system 1100 also includes the fabrication tool 1170 coupled to the processor 1120. The fabrication tool 1170 is configured to fabricate integrated circuits, e.g., the integrated circuit in FIGS. 1 and 2A-2B, according to the design files processed by the processor 1120.

The EDA system 1100 is configured to receive information through I/O interface 1110. The information received through the I/O interface 1110 includes one or more of instructions, data, design rules, libraries of standard cells, and/or other parameters for processing by the processor 1120. The information is transferred to the processor 1120 via the bus 1150. The EDA system 1100 is configured to receive information related to a user interface (UI) through the I/O interface 1110. The information is stored in computer-readable storage medium 1160 as user interface (UI) 1163.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by the EDA system 1100. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, for example, one or more of an optical disk, such as a DVD, a magnetic disk, such as a hard disk, a semiconductor memory, such as a ROM, a RAM, a memory card, and the like.

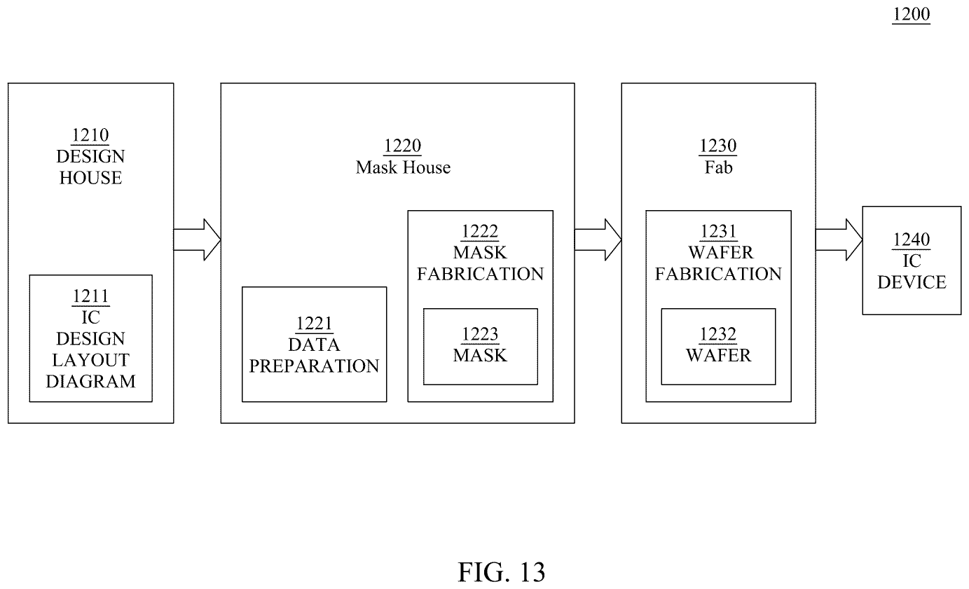

FIG. 13 is a block diagram of IC manufacturing system 1200, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using the IC manufacturing system 1200.

In FIG. 13, the IC manufacturing system 1200 includes entities, such as a design house 1210, a mask house 1220, and an IC manufacturer/fabricator (“fab”) 1230, that interact with one another in the design, development, and manufacturing cycles and/or services related to manufacturing an IC device 1240. The entities in IC manufacturing system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1210, mask house 1220, and IC fab 1230 is owned by a single larger company. In some embodiments, two or more of design house 1210, mask house 1220, and IC fab 1230 coexist in a common facility and use common resources.

Design house (or design team) 1210 generates an IC design layout diagram 1211. The IC design layout diagram 1211 includes various geometrical patterns, for example, an IC layout design depicted in FIGS. 5A-5D and 6-10. The geometrical patterns correspond to patterns of metal, oxide, or semiconductor layers that make up the various components of IC device 1240 to be fabricated. The various layers combine to form various IC features. For example, a portion of IC design layout diagram 1211 includes various IC features, such as an active region, gate electrode, source and drain, conductive segments or vias of an interlayer interconnection, to be formed in a semiconductor substrate (such as a silicon wafer) and various material layers disposed on the semiconductor substrate. Design house 1210 implements a proper design procedure to form IC design layout diagram 1211. The design procedure includes one or more of logic design, physical design or place and route. The IC design layout diagram 1211 is presented in one or more data files having information of the geometrical patterns. For example, the IC design layout diagram 1211 can be expressed in a GDSII file format or DFII file format.

The mask house 1220 includes data preparation 1221 and mask fabrication 1222. The mask house 1220 uses the IC design layout diagram 1211 to manufacture one or more masks 1223 to be used for fabricating the various layers of IC device 1240 according to the IC design layout diagram 1211. The mask house 1220 performs mask data preparation 1221, where IC design layout diagram 1211 is translated into a representative data file (“RDF”). The mask data preparation 1221 provides the RDF to the mask fabrication 1222. The mask fabrication 1222 includes a mask writer. A mask writer converts the RDF to an image on a substrate, such as a mask (reticle) 1223 or a semiconductor wafer 1232. The IC design layout diagram 1211 is manipulated by the mask data preparation 1221 to comply with particular characteristics of the mask writer and/or requirements of the IC fab 1230. In FIG. 13, the data preparation 1221 and the mask fabrication 1222 are illustrated as separate elements. In some embodiments, the data preparation 1221 and the mask fabrication 1222 can be collectively referred to as mask data preparation.

In some embodiments, the data preparation 1221 includes optical proximity correction (OPC) which uses lithography enhancement techniques to compensate for image errors, such as those that can arise from diffraction, interference, other process effects and the like. The OPC adjusts the IC design layout diagram 1211. In some embodiments, the data preparation 1221 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats the OPC as an inverse imaging problem.

In some embodiments, data preparation 1221 includes a mask rule checker (MRC) that checks the IC design layout diagram 1211 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1211 to compensate for limitations during the mask fabrication 1222, which may undo part of the modifications performed by OPC in order to meet mask creation rules.

In some embodiments, data preparation 1221 includes lithography process checking (LPC) that simulates processing that will be implemented by the IC fab 1230 to fabricate the IC device 1240. The LPC simulates this processing based on IC design layout diagram 1211 to create a simulated manufactured device, such as IC device 1240. The processing parameters in LPC simulation can include parameters associated with various processes of the IC manufacturing cycle, parameters associated with tools used for manufacturing the IC, and/or other aspects of the manufacturing process. The LPC takes into account various factors, such as aerial image contrast, depth of focus (“DOF”), mask error enhancement factor (“MEEF”), other suitable factors, and the like or combinations thereof. In some embodiments, after a simulated manufactured device has been created by the LPC, if the simulated device is not close enough in shape to satisfy design rules, the OPC and/or the MRC are be repeated to further refine the IC design layout diagram 1211.

It should be understood that the above description of data preparation 1221 has been simplified for the purposes of clarity. In some embodiments, data preparation 1221 includes additional features such as a logic operation (LOP) to modify the IC design layout diagram 1211 according to manufacturing rules. Additionally, the processes applied to IC design layout diagram 1211 during data preparation 1221 may be executed in a variety of different orders.

After the data preparation 1221 and during mask fabrication 1222, a mask 1223 or a group of masks 1223 are fabricated based on the modified IC design layout diagram 1211. In some embodiments, the mask fabrication 1222 includes performing one or more lithographic exposures based on the IC design layout diagram 1211. In some embodiments, an electron-beam (e-beam) or a mechanism of multiple e-beams is used to form a pattern on a mask (photomask or reticle) 1223 based on the modified IC design layout diagram 1211. The mask 1223 can be formed in various technologies. In some embodiments, the mask 1223 is formed using binary technology. In some embodiments, a mask pattern includes opaque regions and transparent regions. A radiation beam, such as an ultraviolet (UV) beam, used to expose the image sensitive material layer (for example, photoresist) which has been coated on a wafer, is blocked by the opaque region and transmits through the transparent regions. In one example, a binary mask version of the mask 1223 includes a transparent substrate (for example, fused quartz) and an opaque material (for example, chromium) coated in the opaque regions of the binary mask. In another example, the mask 1223 is formed using a phase shift technology. In a phase shift mask (PSM) version of the mask 1223, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1222 is used in a variety of processes. For example, such a mask(s) is used in an ion implantation process to form various doped regions in the semiconductor wafer 1232, in an etching process to form various etching regions in the semiconductor wafer 1232, and/or in other suitable processes.

The IC fab 1230 includes wafer fabrication 1231. The IC fab 1230 is an IC fabrication business that includes one or more manufacturing facilities for the fabrication of a variety of different IC products. In some embodiments, the IC Fab 1230 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

The IC fab 1230 uses mask(s) 1223 fabricated by mask house 1220 to fabricate the IC device 1240. Thus, the IC fab 1230 at least indirectly uses IC design layout diagram 1211 to fabricate the IC device 1240. In some embodiments, the semiconductor wafer 1233 is fabricated by the IC fab 1230 using the mask(s) 1223 to form IC device 1240. In some embodiments, the IC fabrication includes performing one or more lithographic exposures based at least indirectly on the IC design layout diagram 1211. Semiconductor wafer 1233 includes a silicon substrate or other proper substrate having material layers formed thereon. The semiconductor wafer 1233 further includes one or more of various doped regions, dielectric features, multilevel interconnects, and the like (formed at subsequent manufacturing steps).

As described above, embodiments of the present disclosure provide a memory device and a method to manufacture the memory device. The memory device has optimized cell scaling capability and metal conductor RC reduction with the double side (front side and backside) layout. The backside of the memory device serves for conductors (metal lines, vias, etc.) of the supply voltages VSS and/or VDD. The bump pads and bumping are arranged at the backside. Therefore, the power conductors can be directly connected to power bumps (or having shorter path) and IR drop is reduced. In some embodiments, the front side metal one layer is served for bit lines. The front side metal two layer is only served for word lines. The widths of the bit lines and word lines can be maximized. In addition, the proposed fully symmetry layouts of cell groups of the memory device help improve the cell stability (avoiding device mismatch).

In some embodiments, a memory device is provided. The memory device comprises multiple cell groups arranged along a first direction and a second direction perpendicular to the first direction. Each cell group comprises a first bit cell and a second bit cell arranged next to the first bit cell along the first direction. The first bit cell is coupled to a first word line extending along the first direction, and the second bit cell is coupled to a second word line extending along the first direction. The first bit cell and the second bit cell share a bit line extending along the second direction.

In some embodiments, a memory device is provided. The memory device comprises multiple cell groups arranged along a first direction and a second direction perpendicular to the first direction. Each cell group comprises: a first bit cell and a second bit cell. The first bit cell comprises: a first active area and a second active area that extend along the second direction, wherein the second active area is coupled to a bit line; and a first gate structure and a second gate structure that extend along the first direction and are coupled to a first word line. The second bit cell comprising: a third active area that extends along the second direction and is coupled to the bit line; and a third gate structure aligned with the first gate structure along the first direction and separated from the first gate structure along the first direction, wherein the third gate structure is coupled to a second word line.

In some embodiments, a method of manufacturing a memory device is provided. The method comprises: forming a first active area and a second active area that extend along a first direction; forming a first gate structure and a second gate structure that extend along a second direction perpendicular to the first direction and cross the first active area, wherein the first gate structure and the first active area correspond to a first transistor of a first bit cell, wherein the second gate structure and the first active area correspond to a second transistor of the first bit cell; forming a third gate structure that is aligned with the first gate structure along the second direction, wherein the third gate structure and the second active area correspond to a transistor of a second bit cell; forming a first metal line that extends along the first direction and is coupled to the first and second active area, wherein the first metal line is configured as a bit line shared by the first and second bit cells; and forming a second metal line that extends along the second direction and is coupled to the first and second gate structures, wherein the second metal line is configured as a first word line of the first bit cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a plurality of cell groups arranged along a first direction and a second direction perpendicular to the first direction, wherein each cell group comprises:
a first bit cell and a second bit cell arranged next to the first bit cell along the first direction,
wherein the first bit cell is coupled to a first word line extending along the first direction, and the second bit cell is coupled to a second word line extending along the first direction,
wherein the first bit cell and the second bit cell share a bit line extending along the second direction.

2. The memory device of claim 1, wherein the first bit cell comprises:
a first inverter;
a second inverter cross-coupled to the first inverter; and
a first transistor coupled between the bit line and the first inverter, wherein a gate terminal of the first transistor is coupled to the first word line, wherein the second bit cell comprises:
a third inverter; and
a second transistor coupled between the bit line and the third inverter, wherein a gate terminal of the second transistor is coupled to the second word line.

3. The memory device of claim 2, wherein the first bit cell and the second bit cell are symmetric to each other.

4. The memory device of claim 2, further comprising:
a first active area and a second active area that extend along the second direction; and
a first gate structure and a second gate structure that extend along the first direction and cross the first active area,
wherein the first inverter comprises a third transistor and a fourth transistor, and the second inverter comprises a fifth transistor and a sixth transistor,
wherein the first gate structure and the first active area are included in the third transistor, and the first gate structure and the second active area are included in the fourth transistor,
wherein the second gate structure and the first active area are included in the fifth transistor, and the second gate structure and the second active area are included in the sixth transistor,
wherein a portion of the first active area between the first and second gate structures is coupled to a first backside metal line in a backside of the memory device.

5. The memory device of claim 4, wherein a portion of the second active area between the first and second gate structures is coupled to a second backside metal line in the backside,
wherein the first backside metal line is configured to transmit a first supply voltage, and the second backside metal line is configured to transmit a second supply voltage different from the first supply voltage.

6. The memory device of claim 4, further comprising:
a third gate structure and a fourth gate structure that extend along the first direction and cross the first and second active areas,
wherein the third gate structure and the second active area are included in the first transistor,
wherein the first bit cell further comprises a seventh transistor coupled to a complementary bit line,
wherein the fourth gate structure and the second active area are included in the seventh transistor.

7. The memory device of claim 6, wherein a portion of the first active area between the first gate structure and the third gate structure is coupled to the second gate structure,
wherein a portion of the second active area between the first gate structure and the third gate structure is coupled to the second gate structure.

8. The memory device of claim 7, wherein a portion of the first active area between the second gate structure and the fourth gate structure, and a portion of the second active area between the first gate structure and the third gate structure are coupled together as an output terminal of the second inverter.

9. The memory device of claim 6, further comprising:
a first metal line extending along the second direction and crossing the first to fourth gate structures in a top view, wherein the first metal line corresponds to the bit line; and
a second metal line above the first metal line, wherein the second metal line extends along the first direction and crosses the first and second bit cells,
wherein the second metal line corresponds to the first word line.

10. The memory device of claim 9, wherein the second metal line is coupled to the third and fourth gate structures through a third metal line extending along the second direction, wherein the first and third metal lines are in a same metal layer.

11. A memory device, comprising:
a plurality of cell groups arranged along a first direction and a second direction perpendicular to the first direction, wherein each cell group comprises:
a first bit cell comprising:
a first active area and a second active area that extend along the second direction, wherein the second active area is coupled to a bit line; and
a first gate structure and a second gate structure that extend along the first direction and are coupled to a first word line; and
a second bit cell comprising:
a third active area that extends along the second direction and is coupled to the bit line; and
a third gate structure aligned with the first gate structure along the first direction and separated from the first gate structure along the first direction,
wherein the third gate structure is coupled to a second word line.

12. The memory device of claim 11, wherein the first bit cell further comprises:
a fourth gate structure and a fifth gate structure that cross the first and second active areas, wherein the first active area comprises:
a first active region between the first and fourth gate structures; and
a second active region between the fourth and fifth gate structures, wherein the first and second active regions and the fourth gate structure correspond to a first transistor,
wherein the second active area comprises:
a third active region between the first and fourth gate structures; and
a fourth active region between the fourth and fifth gate structures, wherein the third and fourth active regions and the fourth gate structure correspond to a second transistor, wherein the first and second transistors operate as a first inverter.

13. The memory device of claim 12, wherein the first active area comprises:
a fifth active region between the second and fifth gate structures, wherein the second and fifth active regions and the fifth gate structure correspond to a third transistor,
wherein the second active area comprises:
a sixth active region between the second and fifth gate structures, wherein the fourth and sixth active regions and the fifth gate structure correspond to a fourth transistor, wherein the third and fourth transistors operate as a second inverter cross-coupled to the first inverter.

14. The memory device of claim 13, wherein the first and third active regions and the fifth gate structure are coupled together as a first storage node, wherein a voltage level of the first storage node indicates data stored in the first bit cell.

15. The memory device of claim 12, wherein the second active area further comprises:
a fifth active region between the first gate structure and a first boundary line of the first bit cell, wherein the second active area is coupled to the bit line through the fifth active region; and
a sixth active region between the second gate structure and a second boundary line of the first bit cell, wherein the sixth active region is coupled to a complementary bit line.

16. The memory device of claim 15, wherein the third active area comprises:
a seventh active region between the third gate structure and a first boundary line of the second bit cell, wherein the seventh active region is coupled to the fifth active region and the bit line.

17. The memory device of claim 12, wherein the second active region is coupled to a first power rail in a backside of the memory device,
wherein the fourth active region is coupled to a second power rail in the backside,
wherein the first and second power rails are configured to transmit first and second supply voltages, respectively,
wherein the first supply voltage is higher than the second supply voltage.

18. A method of manufacturing a memory device, comprising:
forming a first active area and a second active area that extend along a first direction;
forming a first gate structure and a second gate structure that extend along a second direction perpendicular to the first direction and cross the first active area, wherein the first gate structure and the first active area correspond to a first transistor of a first bit cell,
wherein the second gate structure and the first active area correspond to a second transistor of the first bit cell;
forming a third gate structure that is aligned with the first gate structure along the second direction,
wherein the third gate structure and the second active area correspond to a transistor of a second bit cell;
forming a first metal line that extends along the first direction and is coupled to the first and second active area, wherein the first metal line is configured as a bit line shared by the first and second bit cells; and
forming a second metal line that extends along the second direction and is coupled to the first and second gate structures, wherein the second metal line is configured as a first word line of the first bit cell.

19. The method of claim 18, further comprising:
forming a via coupled between the first metal line and the first active area, wherein a length of the via along the second direction is greater than a width of the via along the first direction,
wherein the via is partially under the first metal line.

20. The method of claim 18, further comprising:
forming a backside metal line at a backside of the memory device, wherein the backside metal line is coupled to the first active area and is configured as a ground.
